(19) United States
(12) Patent Application Publication
(10) Pub. No.: US 2021/0215986 A1
(43) Pub. Date: Jul. 15, 2021

(54) CU ALLOY TARGET, WIRING FILM, SEMICONDUCTOR DEVICE, AND LIQUID CRYSTAL DISPLAY DEVICE

(71) Applicant: ULVAC, INC., Chigasaki-shi, Kanagawa (JP)

(72) Inventors: Satoru TAKASAWA, Chigasaki-shi (JP); Yasuo NAKADAI, Chigasaki-shi (JP)

(73) Assignee: ULVAC, INC., Chigasaki-shi, Kanagawa (JP)

(21) Appl. No.: 16/965,163

(22) PCT Filed: Jan. 29, 2020
(86) PCT No.: PCT/JP2020/003145

§ 371 Date: Jul. 27, 2020

(30) Foreign Application Priority Data
Apr. 9, 2019 (JP) 2019-074257

(51) Int. Cl. G02F 1/1362

(52) U.S. Cl. CPC G02F 1/136295; G02F 1/136277

(57) ABSTRACT

There is provided a Cu alloy target on a surface of a substrate made at least one of glass and resin produced by an adhering film alloy containing Cu and additive metals, the adhering film formed by sputtering. The additive metals include two or more of metals selected from the group consisting of Mg of 0.5 at % or more and 6 at % or less, Al of 1 at % or more and 15 at % or less, and Si of 0.5 at % or more and 10 at % or less. The adhering film has strong adhesive force that resists removal.

### TECHNICAL FIELD

This application relates to a wiring film used for a minute semiconductor device, and particularly, an electrode layer and a wiring film being in contact with a substrate.

### BACKGROUND

In electrical products such as a flat panel display (FPD) and a thin-film solar cell that have been manufactured in recent years, it is necessary to uniformly dispose transistors on a wide substrate. For this reason, amorphous silicon (including hydrogenated amorphous silicon) that can form a semiconductor layer having uniform characteristics on a large-area substrate is used.

The amorphous silicon can be formed at low temperature and does not adversely affect other materials, but it has the drawback of low mobility. For this reason, an oxide semiconductor that can be formed at low temperature and can form a high-mobility thin film on a large-area substrate attracts attention.

In recent years, it is also attempted to perform uniform brightness display in the large-area FPD by using low-resistance copper thin films in an electrode layer and a wiring film of a transistor in the FPD and a semiconductor integrated circuit, in addition to the high-mobility oxide semiconductor.

Further, in recent years, a liquid crystal display device is required to have bendable flexibility. For this reason, technology for forming a wiring film of the liquid crystal display device on a resin substrate is required.

However, the copper thin film has poor adhesion to glass, an oxide, a compound semiconductor, a resin, or the like, and copper atoms as constituent materials of the copper thin film may diffuse into a semiconductor and an oxide thin film, which results in causing a decrease in reliability.

In particular, since the wiring film and the gate electrode layer are formed on a substrate, the copper thin film has poor adhesion to the glass and the resin, so that the wiring film and the gate electrode layer may be detached from a glass substrate and a resin substrate.

For this reason, an adhering film such as a TiN film or a W film for increasing the adhesion strength between the copper wiring and the substrate is provided between the copper thin film and the substrate, but there is still a problem of increased cost.

Further, it is difficult to dry-etch the copper thin film and therefore it is usually formed by a wet etching method. However, the copper thin film and the adhering film such as the TiN film and the W film cannot be etched with the same etching solution. Therefore, a stacked film having a two-layer structure of the copper thin film and the adhering film cannot be etched by a single etching step, and an adhering film that has adhesion and can be etched with the same etching solution as the copper thin film is required.

### CITATION LIST

### Patent Literature

Patent Literature 1: JP H6-177117 A

Patent Literature 2: JP 2002-294437 A

### SUMMARY

### Technical Problem

Disclosed embodiments have been created to solve the disadvantages of the conventional technology, and an object thereof is to provide a wiring film having high adhesion to a glass substrate, a resin substrate, or a semiconductor layer, and a Cu alloy target to form the wiring film.

### Solution to Problem

In a first embodiment, there is provided a Cu alloy target that is disposed in a sputtering apparatus and is sputtered, wherein the Cu alloy target is made of an adhering film alloy containing Cu and additive metals, and when the number of atoms of the adhering film alloy is 100 at %, the additive metals contain two or more kinds of metals among three kinds of metals consisting of Mg in a range of 0.5 at % or more and 6 at % or less, Al in a range of 1 at % or more and 15 at % or less, and Si in a range of 0.5 at % or more and 10 at % or less.

The adhering film alloy may include C at a content of 50 ppm or less and O at a content of 100 ppm or less.

A Vickers hardness may be in a range of 50 Hv or more and 120 Hv or less.

In a second embodiment, there is provided a wiring film having an adhering film made of an adhering film alloy containing Cu and additive metals, wherein when the number of atoms of the adhering film alloy is 100 at %, the additive metals contain two or more kinds of metals among three kinds of metals consisting of Mg in a range of 0.5 at % or more and 6 at % or less, Al in a range of 1 at % or more and 15 at % or less, and Si in a range of 0.5 at % or more and 10 at % or less.

The adhering film alloy may include C at a content of 50 ppm or less and O at a content of 100 ppm or less.

In a third embodiment, there is provided a semiconductor device having a semiconductor layer, a gate insulating film disposed to contact the semiconductor layer, and a gate electrode layer facing the semiconductor layer with the gate insulating film interposed therebetween, a channel region being provided in a portion facing the gate electrode layer in the semiconductor layer, a source region and a drain region being provided on both sides of the channel region, and a source electrode layer and a drain electrode layer contacting the source region and the drain region, respectively, wherein the gate electrode layer has an adhering film contacting a substrate made of either or both of glass and resin, and a copper thin film contacting the adhering film, the adhering film is made of an adhering film alloy containing Cu and additive metals, and when the number of atoms of the adhering film alloy is 100 at %, the additive metals contain two or more kinds of metals among three kinds of metals consisting of Mg in a range of 0.5 at % or more and 6 at% or less, Al in a range of 1 at % or more and 15 at % or less, and Si in a range of 0.5 at % or more and 10 at % or less.

The adhering film alloy may include C at a content of 50 ppm or less and O at a content of 100 ppm or less.

In a fourth embodiment, there is provided a liquid crystal display device including a substrate made of either or both of glass and resin; a wiring film provided on a surface of the substrate; a pixel electrode layer disposed on the substrate, the pixel electrode layer being electrically connected to the wiring film; a liquid crystal disposed on the pixel electrode layer; and an upper electrode layer disposed on the liquid crystal, wherein the wiring film has an adhering film contacting the substrate, the adhering film is made of an adhering film alloy containing Cu and additive metals, and when the number of atoms of the adhering film alloy is 100 at %, the additive metals contain two or more kinds of metals among three kinds of metals consisting of Mg in a range of 0.5 at % or more and 6 at% or less, Al in a range of 1 at % or more and 15 at% or less, and Si in a range of 0.5 at % or more and 10 at % or less.

The adhering film alloy may include C at a content of 50 ppm or less and O at a content of 100 ppm or less.

### Advantageous Effects

In embodiments, since an adhering film and a copper thin film according to the disclosed embodiments can be etched with the same etching solution, a gate electrode layer and a wiring film according to embodiments can be patterned by one etching step.

Since adhesion between the adhering film and a glass substrate and a resin substrate is high, an electrode layer and a wiring film formed on surfaces thereof are not peeled.

The warp of a Cu alloy target is reduced.

### BRIEF DESCRIPTION OF DRAWINGS

FIG. 1 is a cross-sectional view illustrating a transistor and a liquid crystal display device according to an embodiment.

FIGS. 2A, 2B and 2C are (first) cross-sectional views illustrating steps of manufacturing a transistor and a liquid crystal display device according to an embodiment.

FIGS. 3A, 3 and 3C are (second) cross-sectional views illustrating steps of manufacturing a transistor and a liquid crystal display device according to an embodiment.

FIGS. 4A and 4B are (third) cross-sectional views illustrating steps of manufacturing a transistor and a liquid crystal display device according to an embodiment.

FIG. 5 is a (fourth) cross-sectional view illustrating a step of manufacturing a transistor and a liquid crystal display device according to an embodiment.

FIG. 6 is a diagram illustrating a warp amount.

FIG. 7 shows an example of a sputtering apparatus.

### BEST MODE

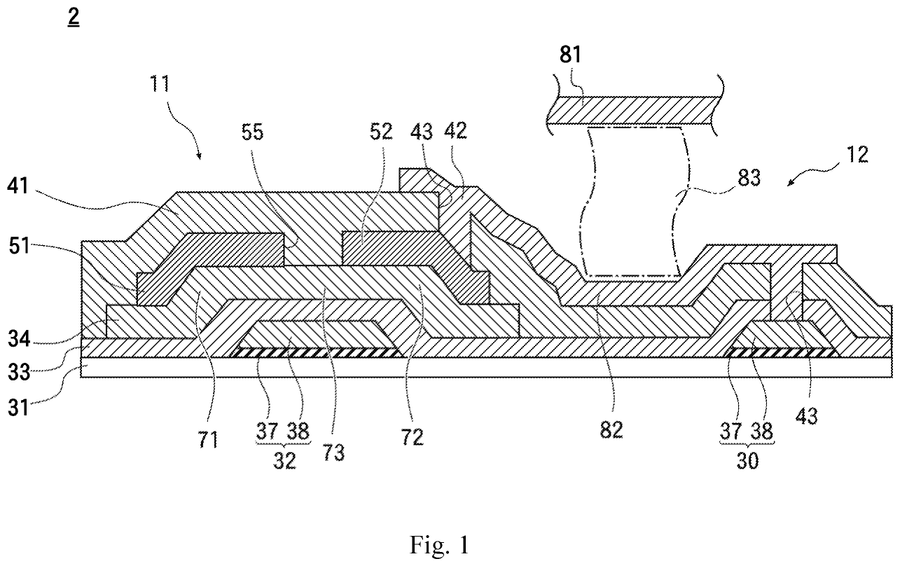

Reference numeral 2 in FIG. 1 illustrates a liquid crystal display device according to an embodiment. In the liquid crystal display device 2, a cross-sectional view of a transistor 11 according to a first example is shown together with a liquid crystal display unit 12.

In the transistor 11, an elongated gate electrode layer 32 is disposed on a surface of a substrate 31 made of either or both of glass and resin, and a gate insulating film 33 made of Si oxide (SiOₓ) is disposed at least in a width direction, on the gate electrode layer 32.

Glass fiber is contained in resin in materials for forming the substrate 31. As such, a substrate formed of a material containing resin and glass and resin is also included.

A semiconductor layer 34 is disposed with a length protruding to the outside of both ends in a width direction of the gate insulating film 33, on the gate insulating film 33. A source electrode layer 51 and a drain electrode layer 52 are formed at the position which is on the semiconductor layer 34, outside the gate electrode layer 32, on both ends in a width direction of the gate electrode layer 32, and facing each other with the gate insulating film 33 interposed therebetween. The source electrode layer 51 and the drain electrode layer 52 are in contact with the semiconductor layer 34.

A recess 55 is provided between the source electrode layer 51 and the drain electrode layer 52, the source electrode layer 51 and the drain electrode layer 52 are electrically isolated by the recess 55, and different voltages can be applied between the source electrode layer 51 and the drain electrode layer 52.

A protective film 41 is formed on the source electrode layer 51, the drain electrode layer 52, and the recess 55 between the source electrode layer 51 and the drain electrode layer 52.

In the transistor 11, if a gate voltage is applied to the gate electrode layer 32 in a state in which the voltage is applied between the source electrode layer 51 and the drain electrode layer 52, and a low-resistance channel layer is formed in a portion of the semiconductor layer 34 facing the gate electrode layer 32 with the gate insulating film 33 interposed therebetween, a portion of the semiconductor layer 34 being in contact with the source electrode layer 51 and a portion of the semiconductor layer 34 being in contact with the drain electrode layer 52 are connected by the channel layer. As a result, the source electrode layer 51 and the drain electrode layer 52 are electrically connected, and the transistor 11 becomes conductive.

Here, polarities of the semiconductor of a source region 71, a drain region 72, and a channel region 73 are the same with each other, and the polarity of the channel layer is the same as the channel region 73.

However, the cases where the polarities of the source region 71 and the drain region 72 are different from the polarity of the channel region 73 and the polarity of the channel layer is the same as the polarities of the source region 71 and the drain region 72 are also encompassed by this disclosure.

If the application of the gate voltage is stopped, the channel layer (or the low-resistance layer) disappears, and a resistance between the source electrode layer 51 and the drain electrode layer 52 becomes high and the source electrode layer 51 and the drain electrode layer 52 is electrically insulated.

A pixel electrode 82 is disposed in the liquid crystal display unit 12, and a liquid crystal 83 is disposed on the pixel electrode 82. An upper electrode 81 is located on the liquid crystal 83, and when a voltage is applied between the pixel electrode 82 and the upper electrode 81, characteristic of polarization of light passing through the liquid crystal 83 is changed, and light transmittance of a polarization filter (not shown) is controlled.

The pixel electrode 82 is electrically connected to the source electrode layer 51 and the drain electrode layer 52, and the transistor 11 is turned on or off to start or stop the voltage application to the pixel electrode 82.

Here, the pixel electrode 82 is made of a part of a transparent conductive layer 42 connected to the drain electrode layer 52. The transparent conductive layer 42 is made of ITO.

A wiring film 30 is disposed under the transparent conductive layer 42.

Each of the wiring film 30 and the gate electrode layer 32 includes an adhering film 37 made of an adhering film alloy according to the disclosed embodiments and a copper thin film 38 (thin film containing copper at a content of more than 50 at %) formed on the adhering film 37 and containing copper as a main component. The adhering film 37 contacts the substrate 31, and the copper thin film 38 does not contact the substrate 31.

A process of manufacturing the transistor 11 will now be described.

In the process of manufacturing the transistor 11, first, the substrate 31 as an object to be film-formed is carried into a sputtering apparatus. Reference numeral 80 in FIG. 7 refers to the sputtering apparatus.

The sputtering apparatus 80 has a vacuum chamber 89, and the inside of the vacuum chamber 89 is evacuated by a vacuum exhaust device 86.

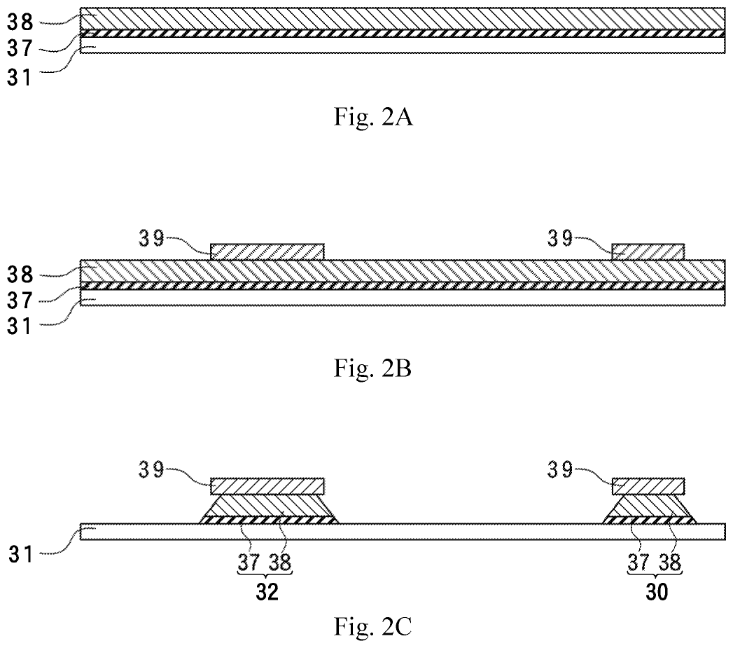

In the vacuum chamber 89, first and second cathode electrodes 86a and 86b are disposed. The first cathode electrode 86a is provided with a Cu alloy target 88a made of an adhering film alloy, and the second cathode electrode 86b is provided with a pure copper target 88b. Sputtering gas made of rare gas such as Ar gas is introduced from a gas source 87 into the vacuum chamber 89, a sputtering voltage is applied to the first cathode electrode 86a by a first sputtering power supply 85a to sputter the Cu alloy target 88a, and as shown in FIG. 2A, the adhering film 37 is formed on the substrate 31.

Next, in this example, the same kind of sputtering gas made of the rare gas is introduced from the gas source 87 into the vacuum chamber 89, and the pure copper target 88b is sputtered to form the copper thin film 38 on the adhering film 37.

The substrate 31 on which the adhering film 37 and the copper thin film 38 are formed is moved to the outside of the vacuum chamber 89.

When the adhering film 37 and the copper thin film 38 are formed, oxygen gas is not introduced into the sputtering atmosphere. Therefore, the adhering film 37 and the copper thin film 38 do not contain copper oxide, and the adhering film 37 and the copper thin film 38 with the low resistance are formed.

After the copper thin film 38 is formed, the copper thin film 38 may be heated to about 400° C. in a desired atmosphere and annealed.

Next, as shown in FIG. 2B, patterned resist films 39 are disposed on the copper thin film 38, the substrate 31 on which the adhering film 37 and the copper thin film 38 are formed is immersed in an etching solution capable of etching both the copper thin film 38 and the adhering film 37, the copper thin film 38 exposed between the resist films 39 and the adhering film 37 exposed after the etching of the copper thin film 38 are brought into contact with the same etching solution, and portions in contact with the etching solution are removed by etching. FIG. 2C shows a state in which the portions are removed by etching.

The substrate 31 on which the adhering film 37 and the copper thin film 38 are formed may be immersed in a pure copper etching solution capable of etching pure copper, and the copper thin film 38 exposed to a bottom surface of an opening provided in the resist film 39 may be removed by etching. Next, the adhering film 37 may be removed by etching by immersing the adhering film 37 in an etching solution for the adhering film capable of etching the adhering film alloy.

In this example, the copper thin film 38 and the adhering film 37 are partially removed, and the gate electrode layer 32 and the wiring film 30 are formed on the substrate 31 by the remaining portions.

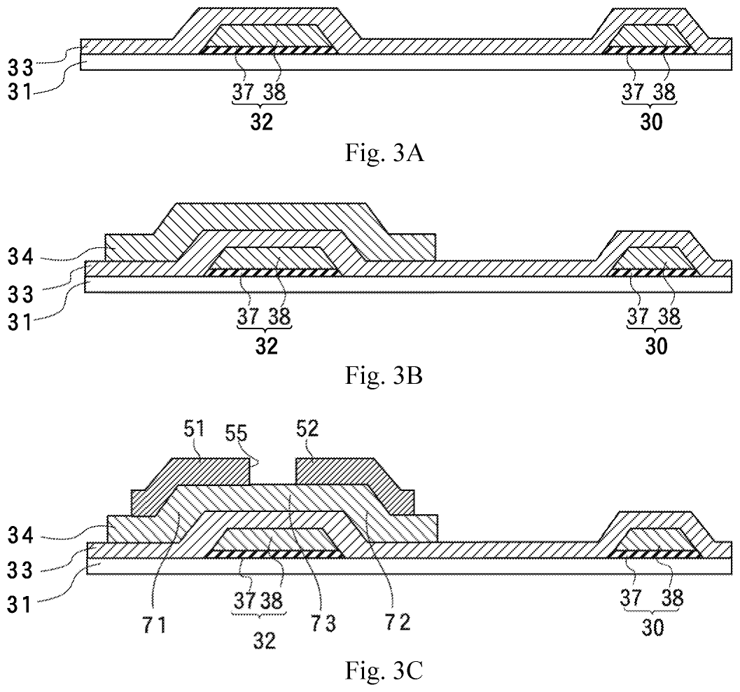

Next, if the gate electrode layer 32 and the wiring film 30 are formed by patterning, the surface of the substrate 31 is exposed except for the portions where the gate electrode layer 32 and the wiring film 30 are located. After removing the resist film 39, as shown in FIG. 3A, the gate insulating film 33 made of an insulating material such as SiO₂ or SiNₓ is formed on the surface of the substrate 31, the surface of the gate electrode layer 32, and the surface of the wiring film 30. The gate insulating film 33 is patterned as needed.

Next, a thin film made of a semiconductor material (for example, a Si semiconductor or an oxide semiconductor) is formed on the gate insulating film 33 and patterned. As shown in FIG. 3B, the patterned semiconductor layer 34 is formed on the gate insulating film 33.

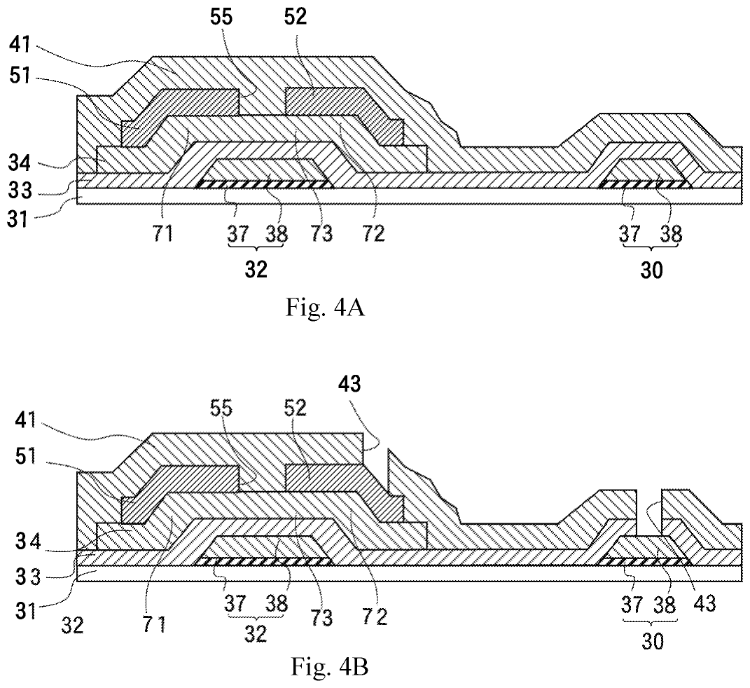

Next, a metal thin film is formed on at least the surface of the semiconductor layer 34. The metal thin film is patterned to form the source electrode layer 51 and the drain electrode layer 52, as shown in FIG. 3C. A portion of the semiconductor layer 34 that contacts the source electrode layer 51 is called the source region 71, and a portion of the semiconductor layer 34 that contacts the drain electrode layer 52 is called the drain region 72. The source electrode layer 51 and the drain electrode layer 52 are disposed at the positions which are, on semiconductor layer 34, on both ends in the width direction of the gate electrode layer 32, and facing the ends of the gate electrode layer 32 with the gate insulating film 33 interposed therebetween. Next, as shown in FIG. 4A, the protective film 41 made of an insulating film such as SiNₓ or SiO₂ is formed.

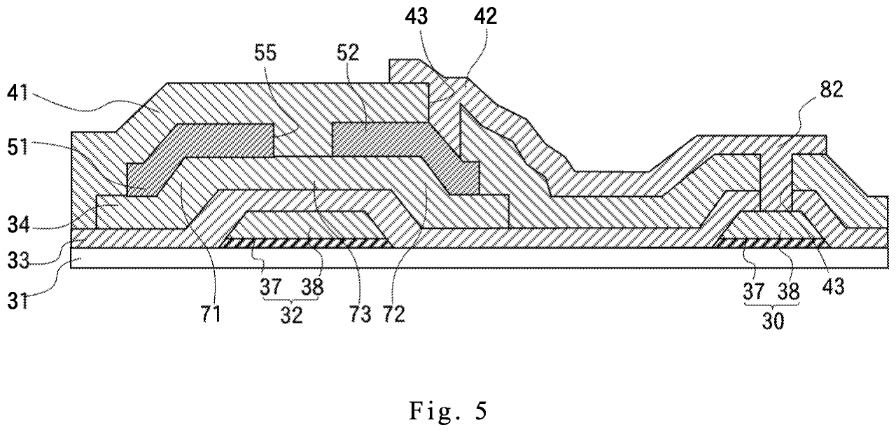

Next, as shown in FIG. 4B, a connection hole 43 such as a via hole or a contact hole is formed in each of the protective film 41 and the gate insulating film 33, and the surface of the drain electrode layer 52, the source electrode layer 51, or the copper thin film 38 included in the wiring film 30 is exposed to a bottom surface of the connection hole 43. In that state, a transparent conductive layer is formed and patterned. Reference numeral 42 in FIG. 5 indicates the patterned transparent conductive layer.

Then, if the liquid crystal 83 and the upper electrode 81 are disposed in a subsequent step to obtain the liquid crystal display device 2 shown in FIG. 1, the transistor 11 can be operated.

The channel region 73 is a region of the semiconductor layer 34 between the source region 71 and the drain region 72, and the gate electrode layer 32 is disposed at a position facing the channel region 73 with at least the gate insulating film 33 interposed therebetween. The transistor 11 is configured by the gate insulating film 33, the gate, source, and drain electrode layers 32, 51, and 52, and the semiconductor layer 34 as described above.

The semiconductor layer 34 includes various semiconductors such as an oxide semiconductor such as InGaZnO (IGZO), an amorphous semiconductor made of Si, a polycrystalline semiconductor, and a single crystal semiconductor.

When the semiconductor layer 34 is configured by IGZO, the source electrode layer 51 and the drain electrode layer 52 are configured by the wiring film 30, the adhering film 37 in the wiring film 30 is brought into contact with the semiconductor layer 34, and the copper thin film 38 is formed on the adhering film, so that it is possible to bring the adhering film 37 into contact with IGZO.

Further, in the above embodiment, the stacked film of the adhering film 37 and the copper thin film 38 is used for the wiring film 30 and the gate electrode layer 32. However, when the source electrode layer 51 and the drain electrode layer 52 of a MOS transistor contact the substrate 31, the source electrode layer and the drain electrode layer can be configured by the stacked film of the adhering film 37 and the copper thin film 38.

### EXAMPLES

An adhering film alloy using copper (Cu) as a main component and containing additive metals is produced, and a Cu alloy target made of the adhering film alloy is produced.

The adhering film alloy is made of an adhering film alloy containing Cu and additive metals. When the number of atoms of the adhering film alloy is 100 at %, the additive metals contain two or more kinds of metals among three kinds of metals consisting of Mg in a range of 0.5 at % or more and 6 at % or less, Al in a range of 1 at % or more and 15 at % or less, and Si in a range of 0.5 at % or more and 10 at % or less.

The adhesion of the adhering film formed by sputtering the adhering film alloy to the substrate greatly changes depending on the contents of carbon atoms (C) and oxygen atoms (O) contained in the adhering film alloy. C is contained in 50 ppm or less and O is contained in 100 ppm or less.

<Evaluation Content>

The Vickers hardness, the workability, the hardness distribution, and the film thickness distribution of the Cu alloy target produced from the adhering film alloy are measured.

For the Vickers hardness, a measurement value in a range of 50 Hv or more and 120 Hv or less is regarded as a good product.

At the time of being alloyed, the hardness increases, the machinability is deteriorated, and deformation occurs during machining. A sputtering rate also tends to decrease. A measurement value not included in the range of 50 Hv or more and 120 Hv or less is evaluated as a defective product.

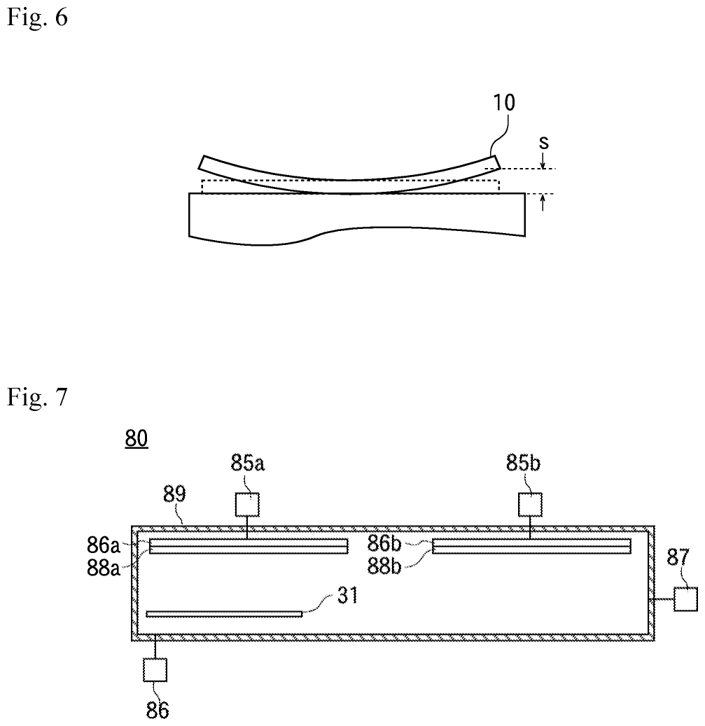

The workability is evaluated by a warp amount of a Cu alloy target obtained by milling an adhering film alloy sheet of 1 m×1 m×20 mm^{t} by a thickness of 5 mm. Reference numeral 10 in FIG. 6 indicates the Cu alloy target obtained by milling, and reference numeral s indicates the warp amount of the Cu alloy target 10. When the warp amount s is 1 mm or more, a corresponding product is evaluated as a defective product.

For the hardness distribution, the hardness is measured at a plurality of positions on a surface of the Cu alloy target produced from the adhering film alloy, the hardness distribution is calculated by the following formula from a maximum hardness value (Max) and a minimum hardness value (Min) of measurement results, and a Cu alloy target having a hardness distribution of 15% or more is evaluated as a defective product.

Hardness distribution=(maximum hardness value−minimum hardness value)/(maximum hardness value+minimum hardness value)

For the sputtering rate, when the Cu alloy target produced from the adhering film alloy is sputtered and a thin film with the same area as the Cu alloy target is formed, a maximum film thickness value and a minimum film thickness value in a thin film surface are measured, a film thickness distribution is calculated from the following formula, and a Cu alloy target having a film thickness distribution of 5% or more is evaluated as a defective product.

Film thickness distribution=(maximum film thickness value−minimum film thickness value)/(maximum film thickness value+minimum film thickness value)

Further, when the Cu alloy target produced from the adhering film alloy is sputtered, an adhering film is formed on each of surfaces of a glass substrate, an epoxy resin substrate, and a polyimide resin substrate, the adhering film is cut into squares of 1 cm×1 cm to form 100 masses made of small pieces of the adhering film, adhesive tape is pasted on each mass, and the adhesive tape is removed from the substrate, a case where even one is removed between the substrates and the masses is evaluated as a defective product (100 mass evaluation in a tape test).

Cu—Mg—Al (1)

An adhering film alloy containing magnesium atoms (Mg) of 0.5, 2, 6, or 8 at % and aluminum atoms (Al) of 0, 1, 2, 8, 10, 15, and 20 at % as additive metals is produced, and each measurement item when the Cu alloy target is produced is evaluated. The evaluation results, the content of C, and the content of O are shown in the following Tables 1 to 4. ◯ indicates a good product, and x indicates a defective product.

Tables 1 to 4 also include measurement values when a Cu alloy target of Cu not containing Mg, Al, and Si is produced. The same is applied to Table 5 and the subsequent Tables.

Cu-0.5 at % Mg—Al

TABLE 1
Cu-0.5 at % Mg—Al

| | | | Cu alloy target | | | | | | | | |
|---|---|---|---|---|---|---|---|---|---|---|---|
| Cu alloy target | | | composition | | Adhesion to base | | | | | | Film |
| compostion (at %) | | | (ppm) | | | Epoxy | | Hardness | | Hardness | thickness |
| Mg | Al | Si | C | O | Glass | resin | Polyimide | (Hv) | Workability | distribution | distribution |
| 0 | 0 | 0 | 10 | 10 | x | x | x | ∘ | ∘ | ∘ | ∘ |
| 0.5 | 1 | 0 | 10 | 10 | ∘ | ∘ | ∘ | ∘ | ∘ | ∘ | ∘ |
| 0.5 | 2 | 0 | 10 | 30 | ∘ | ∘ | ∘ | ∘ | ∘ | ∘ | ∘ |
| 0.5 | 8 | 0 | 20 | 40 | ∘ | ∘ | ∘ | ∘ | ∘ | ∘ | ∘ |
| 0.5 | 10 | 0 | 30 | 60 | ∘ | ∘ | ∘ | ∘ | ∘ | ∘ | ∘ |
| 0.5 | 15 | 0 | 50 | 100 | ∘ | ∘ | ∘ | ∘ | ∘ | ∘ | ∘ |
| 0.5 | 20 | 0 | 60 | 110 | x | x | x | x | x | x | x |
| 0.5 | 2 | 0 | 60 | 120 | x | x | x | x | x | x | x |
| 0.5 | 8 | 0 | 60 | 150 | x | x | x | x | x | x | x |
| 0.5 | 10 | 0 | 70 | 150 | x | x | x | x | x | x | x |

Cu-2 at % Mg—Al

### [Table 2]

TABLE 2
Cu-2 at % Mg—Al

| | | | Cu alloy target | | | | | | | | |
|---|---|---|---|---|---|---|---|---|---|---|---|
| Cu alloy target | | | composition | | Adhesion to base | | | | | | Film |
| compostion (at %) | | | (ppm) | | | Epoxy | | Hardness | | Hardness | thickness |
| Mg | Al | Si | C | O | Glass | resin | Polyimide | (Hv) | Workability | distribution | distribution |
| 0 | 0 | 0 | 10 | 10 | x | x | x | ∘ | ∘ | ∘ | ∘ |
| 2 | 1 | 0 | 10 | 10 | ∘ | ∘ | ∘ | ∘ | ∘ | ∘ | ∘ |
| 2 | 2 | 0 | 20 | 30 | ∘ | ∘ | ∘ | ∘ | ∘ | ∘ | ∘ |
| 2 | 8 | 0 | 30 | 40 | ∘ | ∘ | ∘ | ∘ | ∘ | ∘ | ∘ |
| 2 | 10 | 0 | 30 | 50 | ∘ | ∘ | ∘ | ∘ | ∘ | ∘ | ∘ |
| 2 | 15 | 0 | 50 | 100 | ∘ | ∘ | ∘ | ∘ | ∘ | ∘ | ∘ |
| 2 | 20 | 0 | 70 | 120 | x | x | x | x | x | x | x |
| 2 | 2 | 0 | 70 | 120 | x | x | x | x | x | x | x |
| 2 | 8 | 0 | 60 | 130 | x | x | x | x | x | x | x |
| 2 | 10 | 0 | 80 | 160 | x | x | x | x | x | x | x |

Cu-6 at % Mg—Al

TABLE 3
Cu-6 at % Mg—Al

| | | | Cu alloy target | | | | | | | | |
|---|---|---|---|---|---|---|---|---|---|---|---|
| Cu alloy target | | | composition | | Adhesion to base | | | | | | Film |
| compostion (at %) | | | (ppm) | | | Epoxy | | Hardness | | Hardness | thickness |
| Mg | Al | Si | C | O | Glass | resin | Polyimide | (Hv) | Workability | distribution | distribution |
| 0 | 0 | 0 | 10 | 10 | x | x | x | ∘ | ∘ | ∘ | ∘ |
| 6 | 1 | 0 | 30 | 50 | ∘ | ∘ | ∘ | ∘ | ∘ | ∘ | ∘ |
| 6 | 2 | 0 | 30 | 60 | ∘ | ∘ | ∘ | ∘ | ∘ | ∘ | ∘ |
| 6 | 8 | 0 | 40 | 80 | ∘ | ∘ | ∘ | ∘ | ∘ | ∘ | ∘ |
| 6 | 10 | 0 | 40 | 90 | ∘ | ∘ | ∘ | ∘ | ∘ | ∘ | ∘ |
| 6 | 15 | 0 | 50 | 100 | ∘ | ∘ | ∘ | ∘ | ∘ | ∘ | ∘ |
| 6 | 20 | 0 | 80 | 130 | x | x | x | x | x | x | x |
| 6 | 2 | 0 | 70 | 120 | x | x | x | x | x | x | x |
| 6 | 8 | 0 | 70 | 140 | x | x | x | x | x | x | x |
| 6 | 10 | 0 | 90 | 180 | x | x | x | x | x | x | x |

Cu-8 at % Mg—Al

TABLE 4
Cu-8 at % Mg—Al

| | | | Cu alloy target | | | | | | | | |
|---|---|---|---|---|---|---|---|---|---|---|---|
| Cu alloy target | | | composition | | Adhesion to base | | | | | | Film |
| compostion (at %) | | | (ppm) | | | Epoxy | | Hardness | | Hardness | thickness |
| Mg | Al | Si | C | O | Glass | resin | Polyimide | (Hv) | Workability | distribution | distribution |
| 0 | 0 | 0 | 10 | 10 | x | x | x | ∘ | ∘ | ∘ | ∘ |
| 8 | 1 | 0 | 50 | 110 | x | x | x | x | x | x | x |
| 8 | 2 | 0 | 50 | 110 | x | x | x | x | x | x | x |
| 8 | 8 | 0 | 60 | 120 | x | x | x | x | x | x | x |
| 8 | 10 | 0 | 60 | 130 | x | x | x | x | x | x | x |
| 8 | 15 | 0 | 80 | 200 | x | x | x | x | x | x | x |
| 8 | 20 | 0 | 80 | 230 | x | x | x | x | x | x | x |

Cu—Al—Si (2)

An adhering film alloy containing Al of 1, 5, 10, 15, or 20 at % and silicon atoms (Si) of 0.5, 1, 2, 5, 10, or 15 at % as additive metals is produced, and each measurement item when the Cu alloy target is produced is evaluated. The evaluation results, the content of C, and the content of O are shown in the following Tables 5 to 9. ◯ indicates a good product, and x indicates a defective product.

Cu-1 at % Al—Si

TABLE 5
Cu-1 at % Al—Si

| | | | Cu alloy target | | | | | | | | |
|---|---|---|---|---|---|---|---|---|---|---|---|
| Cu alloy target | | | composition | | Adhesion to base | | | | | | Film |
| compostion (at %) | | | (ppm) | | | Epoxy | | Hardness | | Hardness | thickness |
| Mg | Al | Si | C | O | Glass | resin | Polyimide | (Hv) | Workability | distribution | distribution |
| 0 | 0 | 0 | 10 | 10 | x | x | x | ∘ | ∘ | ∘ | ∘ |
| 0 | 1 | 0.5 | 10 | 10 | ∘ | ∘ | ∘ | ∘ | ∘ | ∘ | ∘ |
| 0 | 1 | 1 | 10 | 30 | ∘ | ∘ | ∘ | ∘ | ∘ | ∘ | ∘ |
| 0 | 1 | 2 | 20 | 40 | ∘ | ∘ | ∘ | ∘ | ∘ | ∘ | ∘ |
| 0 | 1 | 5 | 30 | 60 | ∘ | ∘ | ∘ | ∘ | ∘ | ∘ | ∘ |
| 0 | 1 | 10 | 50 | 100 | ∘ | ∘ | ∘ | ∘ | ∘ | ∘ | ∘ |
| 0 | 1 | 15 | 60 | 110 | x | x | x | x | x | x | x |
| 0 | 1 | 1 | 60 | 120 | x | x | x | x | x | x | x |
| 0 | 1 | 5 | 60 | 150 | x | x | x | x | x | x | x |
| 0 | 1 | 10 | 60 | 160 | x | x | x | x | x | x | x |

Cu-5 at % Al—Si

TABLE 6
Cu-5 at % Al—Si

| | | | Cu alloy target | | | | | | | | |
|---|---|---|---|---|---|---|---|---|---|---|---|
| Cu alloy target | | | composition | | Adhesion to base | | | | | | Film |
| compostion (at %) | | | (ppm) | | | Epoxy | | Hardness | | Hardness | thickness |
| Mg | Al | Si | C | O | Glass | resin | Polyimide | (Hv) | Workability | distribution | distribution |
| 0 | 0 | 0 | 10 | 10 | x | x | x | ∘ | ∘ | ∘ | ∘ |
| 0 | 5 | 0.5 | 10 | 10 | ∘ | ∘ | ∘ | ∘ | ∘ | ∘ | ∘ |
| 0 | 5 | 1 | 10 | 20 | ∘ | ∘ | ∘ | ∘ | ∘ | ∘ | ∘ |
| 0 | 5 | 2 | 30 | 40 | ∘ | ∘ | ∘ | ∘ | ∘ | ∘ | ∘ |
| 0 | 5 | 5 | 40 | 70 | ∘ | ∘ | ∘ | ∘ | ∘ | ∘ | ∘ |
| 0 | 5 | 10 | 50 | 100 | ∘ | ∘ | ∘ | ∘ | ∘ | ∘ | ∘ |
| 0 | 5 | 15 | 60 | 120 | x | x | x | x | x | x | x |
| 0 | 5 | 1 | 60 | 140 | x | x | x | x | x | x | x |
| 0 | 5 | 5 | 80 | 160 | x | x | x | x | x | x | x |
| 0 | 5 | 10 | 80 | 180 | x | x | x | x | x | x | x |

Cu-10 at % Al—Si

TABLE 7
Cu-10 at % Al—Si

| | | | Cu alloy target | | | | | | | | |
|---|---|---|---|---|---|---|---|---|---|---|---|
| Cu alloy target | | | composition | | Adhesion to base | | | | | | Film |
| compostion (at %) | | | (ppm) | | | Epoxy | | Hardness | | Hardness | thickness |
| Mg | Al | Si | C | O | Glass | resin | Polyimide | (Hv) | Workability | distribution | distribution |
| 0 | 0 | 0 | 10 | 10 | x | x | x | ∘ | ∘ | ∘ | ∘ |
| 0 | 10 | 0.5 | 10 | 10 | ∘ | ∘ | ∘ | ∘ | ∘ | ∘ | ∘ |
| 0 | 10 | 1 | 20 | 20 | ∘ | ∘ | ∘ | ∘ | ∘ | ∘ | ∘ |
| 0 | 10 | 2 | 40 | 50 | ∘ | ∘ | ∘ | ∘ | ∘ | ∘ | ∘ |
| 0 | 10 | 5 | 50 | 70 | ∘ | ∘ | ∘ | ∘ | ∘ | ∘ | ∘ |
| 0 | 10 | 10 | 50 | 100 | ∘ | ∘ | ∘ | ∘ | ∘ | ∘ | ∘ |
| 0 | 10 | 15 | 60 | 120 | x | x | x | x | x | x | x |
| 0 | 10 | 1 | 70 | 150 | x | x | x | x | x | x | x |
| 0 | 10 | 5 | 90 | 160 | x | x | x | x | x | x | x |
| 0 | 10 | 10 | 90 | 180 | x | x | x | x | x | x | x |

Cu-15 at % Al—Si

TABLE 8
Cu-15 at % Al—Si

| | | | Cu alloy target | | | | | | | | |
|---|---|---|---|---|---|---|---|---|---|---|---|
| Cu alloy target | | | composition | | Adhesion to base | | | | | | Film |
| compostion (at %) | | | (ppm) | | | Epoxy | | Hardness | | Hardness | thickness |
| Mg | Al | Si | C | O | Glass | resin | Polyimide | (Hv) | Workability | distribution | distribution |
| 0 | 0 | 0 | 10 | 10 | x | x | x | ∘ | ∘ | ∘ | ∘ |
| 0 | 15 | 0.5 | 10 | 10 | ∘ | ∘ | ∘ | ∘ | ∘ | ∘ | ∘ |
| 0 | 15 | 1 | 30 | 30 | ∘ | ∘ | ∘ | ∘ | ∘ | ∘ | ∘ |
| 0 | 15 | 2 | 40 | 50 | ∘ | ∘ | ∘ | ∘ | ∘ | ∘ | ∘ |
| 0 | 15 | 5 | 40 | 80 | ∘ | ∘ | ∘ | ∘ | ∘ | ∘ | ∘ |
| 0 | 15 | 10 | 50 | 100 | ∘ | ∘ | ∘ | ∘ | ∘ | ∘ | ∘ |
| 0 | 15 | 15 | 60 | 120 | x | x | x | x | x | x | x |
| 0 | 15 | 1 | 70 | 150 | x | x | x | x | x | x | x |
| 0 | 15 | 5 | 90 | 160 | x | x | x | x | x | x | x |
| 0 | 15 | 10 | 90 | 180 | x | x | x | x | x | x | x |

Cu-20 at % Al—Si

TABLE 9
Cu-20 at % Al—Si

| | | | Cu alloy target | | | | | | | | |
|---|---|---|---|---|---|---|---|---|---|---|---|
| Cu alloy target | | | composition | | Adhesion to base | | | | | | Film |
| compostion (at %) | | | (ppm) | | | Epoxy | | Hardness | | Hardness | thickness |
| Mg | Al | Si | C | O | Glass | resin | Polyimide | (Hv) | Workability | distribution | distribution |
| 0 | 0 | 0 | 10 | 10 | x | x | x | ∘ | ∘ | ∘ | ∘ |
| 0 | 20 | 0.5 | 60 | 110 | x | x | x | x | x | x | x |
| 0 | 20 | 1 | 70 | 110 | x | x | x | x | x | x | x |
| 0 | 20 | 2 | 80 | 120 | x | x | x | x | x | x | x |
| 0 | 20 | 5 | 90 | 130 | x | x | x | x | x | x | x |
| 0 | 20 | 10 | 90 | 130 | x | x | x | x | x | x | x |
| 0 | 20 | 15 | 90 | 150 | x | x | x | x | x | x | x |

Cu—Mg—Al—Si (3)

An adhering film alloy containing Mg of 1 at %, Al of 2 at %, and Si of 1 or 3 at % as additive metals and an adhering film alloy containing Mg of 2 or 6 at %, Al of 2 or 8 at %, and Si of 2, 5, or 10 at % as additive metals are produced, and each measurement item when the Cu alloy target is produced is evaluated. The evaluation results, the content of C, and the content of O are shown in the following Table 10. ◯ indicates a good product, and x indicates a defective product.

TABLE 10
Cu—Mg—Al—Si

| | | | Cu alloy target | | | | | | | | |
|---|---|---|---|---|---|---|---|---|---|---|---|
| Cu alloy target | | | composition | | Adhesion to base | | | | | | Film |
| compostion (at %) | | | (ppm) | | | Epoxy | | Hardness | | Hardness | thickness |
| Mg | Al | Si | C | O | Glass | resin | Polyimide | (Hv) | Workability | distribution | distribution |
| 0 | 0 | 0 | 10 | 10 | x | x | x | ∘ | ∘ | ∘ | ∘ |
| 1 | 2 | 1 | 10 | 10 | ∘ | ∘ | ∘ | ∘ | ∘ | ∘ | ∘ |
| | | 3 | 10 | 30 | ∘ | ∘ | ∘ | ∘ | ∘ | ∘ | ∘ |
| 2 | 2 | 2 | 20 | 40 | ∘ | ∘ | ∘ | ∘ | ∘ | ∘ | ∘ |
| | | 5 | 20 | 60 | ∘ | ∘ | ∘ | ∘ | ∘ | ∘ | ∘ |
| | | 10 | 30 | 80 | ∘ | ∘ | ∘ | ∘ | ∘ | ∘ | ∘ |
| | 8 | 2 | 20 | 50 | ∘ | ∘ | ∘ | ∘ | ∘ | ∘ | ∘ |
| | | 5 | 30 | 70 | ∘ | ∘ | ∘ | ∘ | ∘ | ∘ | ∘ |
| | | 10 | 40 | 90 | ∘ | ∘ | ∘ | ∘ | ∘ | ∘ | ∘ |
| 6 | 2 | 2 | 20 | 40 | ∘ | ∘ | ∘ | ∘ | ∘ | ∘ | ∘ |
| | | 5 | 30 | 60 | ∘ | ∘ | ∘ | ∘ | ∘ | ∘ | ∘ |
| | | 10 | 50 | 90 | ∘ | ∘ | ∘ | ∘ | ∘ | ∘ | ∘ |
| | 8 | 2 | 40 | 50 | ∘ | ∘ | ∘ | ∘ | ∘ | ∘ | ∘ |
| | | 5 | 40 | 90 | ∘ | ∘ | ∘ | ∘ | ∘ | ∘ | ∘ |
| | | 10 | 50 | 100 | ∘ | ∘ | ∘ | ∘ | ∘ | ∘ | ∘ |

### CONCLUSION

From Tables 1 to 10, it can be seen that the additive metals may contain two or more kinds of metals among three kinds of metals consisting of Mg in the range of 0.5 at % or more and 6 at % or less, Al in the range of 1 at % or more and 15 at % or less, and Si in the range of 0.5 at % or more and 10 at % or less.

Further, it can be seen that the content of C in the adhering film alloy may be 50 ppm or less and the content of 0 may be 100 ppm or less.

When the Cu alloy target is produced from the adhering film alloy, the composition of the Cu alloy target is the same as that of the adhering film alloy, and the composition of the thin film formed by sputtering the Cu alloy target with rare gas is also the same as that of the adhering film alloy.

1. A Cu alloy target that is disposed in a sputtering apparatus and is sputtered, the Cu alloy target including an adhering film alloy comprising:
C: 50 ppm or less;
O: 100 ppm or less;
Cu; and
additive metals,
wherein, when the number of atoms of the adhering film alloy is 100 at %, the additive metals include two or more metals selected from the group consisting of Mg: 0.5 at % or more and 6 at % or less, Al: 1 at % or more and 15 at % or less, and Si: 0.5 at % or more and 10 at % or less.

2. (canceled)

3. The Cu alloy target according to claim 1, wherein a Vickers hardness is in a range of 50 Hv or more and 120 Hv or less.

4. A wiring film having an adhering film including an adhering film alloy comprising:
C: 50 ppm or less;
O: 100 ppm or less;
Cu; and
additive metals,
wherein, when the number of atoms of the adhering film alloy is 100 at %, the additive metals include two or more of metals selected from the group consisting of Mg 0.5 at % or more and 6 at % or less, Al: 1 at % or more and 15 at % or less, and Si: 0.5 at % or more and 10 at % or less.

5. (canceled)

6. A semiconductor device comprising:
a semiconductor layer;
a gate insulating film that contacts the semiconductor layer;
a gate electrode layer facing the semiconductor layer with the gate insulating film interposed therebetween, the gate electrode layer including an adhering film that contacts a substrate comprising at least one of glass and resin;
a channel region provided in a portion of the semiconductor layer, the portion facing the gate electrode layer, and a source region and a drain region provided on both sides of the channel region;
a source electrode layer and a drain electrode layer that contact the source region and the drain region, respectively; and
a copper thin film that contacts the adhering film,
wherein the adhering film includes an adhering film alloy comprising:
C: 50 ppm or less;
O: 100 ppm or less;
Cu; and
additive metals, and
when the number of atoms of the adhering film alloy is 100 at %, the additive metals include two or more of metals selected from the group consisting of Mg: 0.5 at % or more and 6 at % or less, Al: 1 at % or more and 15 at % or less, and Si: 0.5 at % or more and 10 at % or less.

7. (canceled)

8. A liquid crystal display device comprising:
a substrate comprising at least one of glass and resin;
a wiring film provided on a surface of the substrate, the wiring film including an adhering film that contacts the substrate;
a pixel electrode layer disposed on the substrate;
a liquid crystal disposed on the pixel electrode layer; and
an upper electrode layer disposed on the liquid crystal, the pixel electrode layer being electrically connected to the wiring film,
wherein the adhering film includes an adhering film alloy comprising:
C: 50 ppm or less;
O: 100 ppm or less;
Cu; and
additive metals, and
when the number of atoms of the adhering film alloy is 100 at %, the additive metals include two or more of metals selected from the group consisting of Mg: 0.5 at % or more and 6 at % or less, Al: 1 at % or more and 15 at % or less, and Si: 0.5 at % or more and 10 at % or less.

9. (canceled)
